(19) United States
(12) Patent Application Publication
(10) Pub. No.: US 2026/0321341 A1
(43) Pub. Date: Oct. 15, 2026

(54) APPARATUSES, SYSTEMS, AND METHODS FOR DATA STEERING AND COLUMN ADDRESS REMAPPING FOR METADATA STORAGE

(71) Applicant: Micron Technology, Inc., Boise, ID (US)

(72) Inventors: Gary Howe, Allen, TX (US); Sujeet Ayyapureddi, Boise, ID (US)

(73) Assignee: Micron Technology, Inc., Boise, ID (US)

(21) Appl. No.: 19/177,839

(22) Filed: Apr. 14, 2025

(51) Int. Cl. G11C 29/00; G11C 11/4093

(52) U.S. Cl. CPC G11C 29/76; G11C 11/4093; G11C 29/785

(57) ABSTRACT

A bank of a memory device may be divided into column planes. Each column plane may be associated with column selects. In some examples, one or more physical column planes may be selectively configured to store metadata. Depending on the amount of metadata to be stored, the column selects may be arranged into virtual column planes to allow data to be stored in physical column plane(s) used for metadata. The physical column planes may be arranged into virtual planes to store the data. In some examples, data steering circuitry including multiplexers and tri-state drivers may be used to steer data between physical column planes to implement the virtual planes. In some examples, a column decoder may include multiplexers to remap logical addresses to implement the virtual planes.

### BACKGROUND

This disclosure relates generally to semiconductor devices, and more specifically to semiconductor memory devices. In particular, the disclosure relates to memory, such as dynamic random access memory (DRAM). Information may be stored in memory cells, which may be organized into rows (word lines) and columns (bit lines) of an array. Various types of information may be stored in the array, such as data, error correction code (ECC) data, and metadata. The data may be information provided by an external device (e.g., controller, processor, host system). The ECC data may provide information that may be used to detect and/or correct errors in the data. The metadata may provide information about the data, ECC data, the memory device, and/or a device in communication with the memory device (e.g., a controller).

DRAM users are increasingly utilizing metadata to supplement the data stored in the memory array. For example, metadata may be used to store a “poison bit” that indicates that the data associated with the metadata is erroneous and should be discarded and/or replaced by an external device (e.g., controller, host, and/or system on a chip). In another example, metadata may store a pointer to a storage location that may allow the external device to determine what location in the array to access the next associated data. In some applications, this may be analogous to a head and/or tail of a linked list. These are merely examples, and other uses of metadata are also possible.

Metadata may be stored in the memory array in one or more column planes. However, not all users want to use metadata. Further, some users want to store more metadata than other users. Accordingly, memory devices that can satisfy multiple user preferences are desired.

### BRIEF DESCRIPTION OF THE DRAWINGS

FIG. 1 is a block diagram of at least a portion of a computing system according to some embodiments of the present disclosure.

FIG. 2 is a block diagram of a semiconductor device according to some embodiments of the present disclosure.

FIG. 3 is a block diagram of a portion of a memory device according to some embodiments of the present disclosure.

FIG. 4 shows a table indicating organization of a bank of a memory array according to some embodiments of the present disclosure.

FIG. 5 shows a table indicating organization of the bank of the memory array and physical column plane suppression scheme according to some embodiments of the present disclosure.

FIG. 6 shows a table indicating organization of the bank of the memory array and physical column plane suppression scheme according to some embodiments of the present disclosure.

FIG. 7 is a block diagram of a portion of a memory device according to some embodiments of the present disclosure.

FIG. 8 is a circuit diagram of a portion of a memory device according to some embodiments of the present disclosure.

FIG. 9 is a block diagram of a portion of a memory device according to some embodiments of the present disclosure.

FIG. 10 is a block diagram of a portion of a memory device according to some embodiments of the present disclosure.

FIG. 11 is a block diagram of at least a portion of a column decoder according to some embodiments of the present disclosure.

FIG. 12 is a block diagram of a portion of a memory device according to some embodiments of the present disclosure.

FIG. 13 shows a table of example decoding schemes according to some embodiments of the present disclosure.

FIG. 14 is a flow chart of a method according to embodiments of the present disclosure.

FIG. 15 is a flow chart of a method according to embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Semiconductor memory devices may store information in multiple memory cells. The information may be stored as a binary code, and each memory cell may store a single bit of information as either a logical high (e.g., a “1”) or a logical low (e.g., a “0”). The memory cells may be organized at the intersection of word lines (rows) and bit lines (columns) an array. The memory may further be organized into one or more memory banks. The banks may be organized into bank groups, where each bank group includes one or more banks. Each bank may include multiple of rows and columns. During operations, the memory device may receive a command and an address which specifies one or more rows and one or more columns and then execute the command on the memory cells at the intersection of the specified rows and columns (and/or along an entire row/column). The address may further specify the bank group and/or bank for execution of the command. In some applications, rows may be specified by 17-bit row addresses and columns may be specified by 12-bit column addresses. However, the number of bits used for the addresses may vary depending on the size and/or organization of the memory.

The columns may generally be organized into column planes, each of which includes a number of sets of individual columns all activated by a column select signal (CS) (e.g., column selects). Each bank may include some number X column planes. A column plane may receive some number N of column select (CS) signals, each of which may activate some number M of individual bit lines. As used herein, a column select set or CS set may generally refer to a set of bit lines which are activated by a given value of the CS signal within a column plane. The column select signal may be represented by (all or a portion of) a column address (CA). Responsive to a column select signal, data may be provided from corresponding locations from the column planes. The data from the column planes associated with the column select signal may be referred to as a prefetch.

As discussed in the Background section, users may or may not want to store metadata in the memory array. Accordingly, memory devices may include a memory array that is selectively configurable (e.g., enabled) to store different amounts of metadata (e.g., none, 8 bits, and 16 bits per prefetch). For example, the memory array may include 16 column planes for data, two column planes for metadata, and a column plane for ECC data (total=19 CP). When storing a first amount of metadata (e.g., 16 bits) is enabled (e.g., by a mode register), 14 of the data column planes are associated with 56 column select signals, 2 of the data column planes are associated with 60 column select signals, the metadata planes are associated with 60 column select signals, and the ECC data plane is associated with 64 column select signals (total=19 CP). When storing a second amount of metadata less than the first amount (e.g., 8 bits) is enabled, the column select signals may be activated in a manner such that the memory array operates as if there are sixteen data planes, one metadata plane, and an ECC data plane (total=18 CP). When storing metadata is disabled, the column select signals may be activated in a manner such that the memory array operates as if there are sixteen data planes and an ECC data plane (total=17 CP). This is merely one example, and the memory array may be arranged into a different number of column planes and/or different numbers of column planes may be designated for different types of information in other examples.

When the first amount of metadata is stored, the physical column planes (e.g., physical planes) of the memory device associated with data and metadata are accessed by activating the corresponding column select signals for the physical column planes. When the second amount of metadata is stored or when metadata is not stored, the memory device may configure the column select signals to be activated in a manner to form a number of virtual column planes (e.g., virtual planes) to access metadata and/or data. The number of virtual planes may be less than the number of data and metadata physical planes (e.g., 16 data+2 metadata=18 total physical planes vs. 17 or 16 total virtual planes). The number of bit lines activated on the virtual planes may be equal to the number of bits lines activated in the physical planes during a memory access operation. By “virtual planes” it is meant that column select signals may be activated or suppressed in a manner that does not correspond to the physical planes of the memory array of the memory device. However, from the viewpoint of a controller, the memory device may receive and output data and/or metadata as if the virtual planes were physical column planes. For example, when no metadata is stored, the controller “sees” 16 column planes even though the memory array has 18 physical planes.

Organizing the physical planes into virtual planes to accommodate the different metadata storage modes may require steering data to and from different column planes depending on the column address and/or selected storage mode. This may require significant increases in conductive traces across the column planes. This may increase fabrication complexity, risk of noise, and/or increase layout area. Accordingly, implementations that reduce the number of additional conductive traces are desired.

Further, column address mapping within a column plane may require modification depending on the column address and/or selected storage mode. This may prevent circuitry of a column decoder from sharing pre-decode logic and/or increase the amount of decoding logic required. This may increase the required layout area of the column decoder. Accordingly, implementations that reduce the required added logic are desired. As used herein, “circuitry” refers to one or more circuits.

According to embodiments of the present disclosure, a memory device may include data steering circuitry to steer data to the correct column plane. In some embodiments, the data steering circuitry may include one or more multiplexers. The multiplexers may include tri-state drivers. When data is steered to a target column plane, the tri-state driver may be enabled to provide the data to a conductive trace coupled to the target column plane. In some embodiments, the multiplexers may be controlled based on control signals from logic circuits. The logic circuits may implement a lookup table based, at least in part, on the storage mode and the column address associated with the data.

According to embodiments of the present disclosure, a column decoder may selectively remap logical addresses to physical addresses of column selects based on a storage mode of the memory device, a column address, or a combination thereof. In some embodiments, the column decoder may include multiplexers and pre-decode drivers that receive column address information from pre-decode logic. The multiplexers may selectively remap addresses for the column planes. For example, in a default storage mode, the multiplexers may pass the column address information to further column decoder logic unchanged, and in a non-default storage mode, the multiplexers may remap one or more column address information prior to passing to the column decoder logic. The multiplexers may be controlled based on control signals from logic circuits. The logic circuits may implement a lookup table based, at least in part, on the storage mode and the column address associated with the data.

Memory devices disclosed herein may be configured such that one of multiple storage modes is considered a default storage mode. In some embodiments, in the default storage mode, the column planes may not be organized into virtual planes. In some embodiments, in the default storage mode, no data steering or column address remapping may be required. As used herein, “default” or “native” (e.g., default column plane) may refer to a location data or metadata would be stored and/or a location corresponding to a column address when the memory device is in the default storage mode. A “target” may refer to a location data or metadata is stored and/or a location corresponding to a column address when the memory device is in a non-default storage mode. The examples disclosed herein describe memory devices where the default storage mode is to store a total of 16 bits of metadata in two column planes (8 bits in each plane). However, other embodiments of the disclosure may utilize other storage modes as the default storage mode (e.g., default is no metadata is stored).

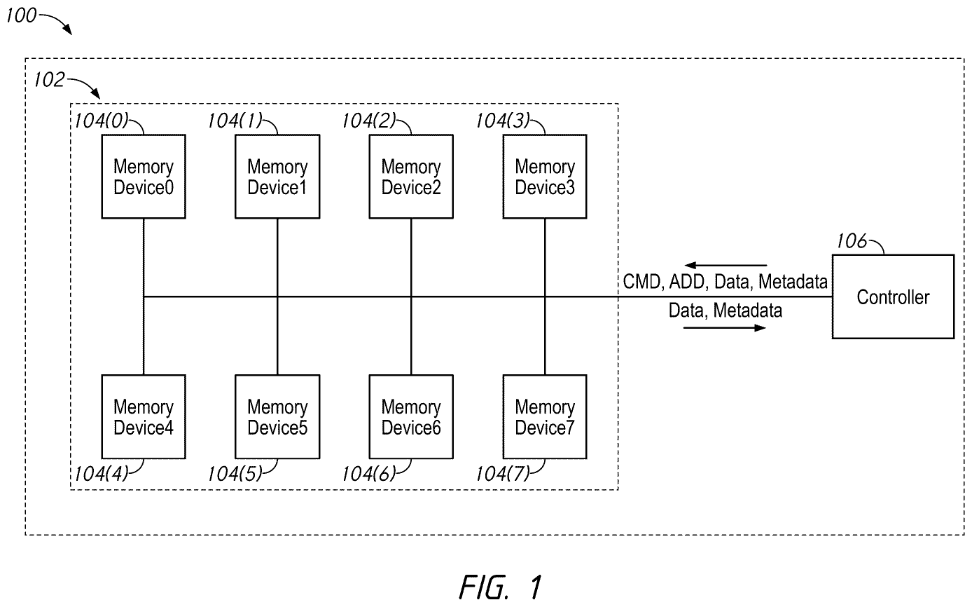

FIG. 1 is a block diagram of at least a portion of a computing system according to some embodiments of the present disclosure. The computing system 100 includes a memory module 102 and a controller 106 in communication with the memory module 102. In some embodiments, the controller 106 may be included in a processor (not shown) or in communication with the processor. The memory module 102 may include one or more memory devices 104. In the example shown in FIG. 1, there are eight memory devices 104(0-7). However, in other embodiments, there may be more or fewer memory devices (e.g., 4 devices, 16 devices). In some embodiments, additional memory devices 104 may be included to provide for redundancy. In some embodiments, memory module 102 may be a dual in-line memory module (DIMM). In some embodiments, what is shown in FIG. 1 may represent only half of the DIMM (e.g., one of the two channels). In other words, memory module 102 may include sixteen memory devices 104.

The controller 106 may provide commands, addresses, and/or data (e.g., data, metadata, or both) to one or more of the memory devices 104 and receive data from one or more of the memory devices 104. In some embodiments, memory devices 104 may be x4 or x8 memory devices. That is, either four or eight DQ terminals (e.g., pins) may be active. In some embodiments, the memory devices 104 may support both x4 and x8 operation. In some embodiments, whether the memory devices 104 operate in x4 or x8 mode may be based, at least in part, on values stored in mode registers (not shown in FIG. 1) of the memory devices 104. In some embodiments, the memory devices 104 may be x16 memory devices.

In some applications, each of the memory devices 104 may provide eight bits of metadata, for a total of four bytes of data. In some applications, each of the memory devices 104 may provide sixteen bits of metadata, for a total of eight bytes of data. The controller 106 may receive a prefetch from the memory devices 104 that include 128 bits of data and either 8 bits or 16 bits of metadata. In some embodiments, how much metadata is provided may be based on a value stored in the mode register of the memory device 104.

How much metadata is stored may be based on a value stored in the mode register of the memory device 104. For example, when one value is stored in the mode register, 8 bits of metadata may be stored, when another value is stored in the mode register 16 bits of metadata may be stored, when a further value is stored in the mode register, metadata may not be stored. When this value is stored, all of the column selects are available for providing data to and from the array. Depending on the amount of metadata stored based on the selected storage mode, the memory arrays of the memory devices 104 may be arranged into virtual planes. As will be described herein, the memory devices 104 may include circuits to accommodate data steering and column address remapping to accommodate the arrangement of the column planes into virtual planes.

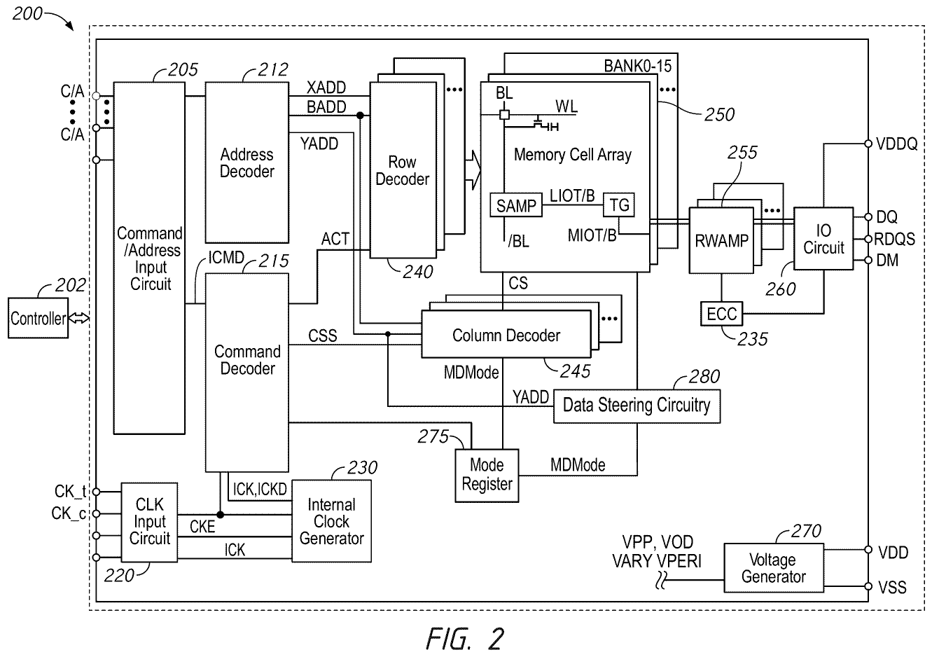

FIG. 2 is a block diagram of a semiconductor device according to some embodiments of the present disclosure. The apparatus may be a semiconductor device, which may be a memory device 200, and will be referred as such. In some embodiments, the memory device 200 may include, without limitation, a dynamic random access (DRAM) device integrated into a single semiconductor chip. In some examples, the DRAM may be a double data rate (DDR) memory. In some embodiments, one or all of the memory devices 104(0-7) of FIG. 1 may include memory device 200.

The memory device 200 may be included on a die. The die may be mounted on an external substrate, for example, a memory module substrate, a mother board or the like (e.g., package-on-package (PoP)). The memory device 200 may include a memory array 250. The memory array 250 includes a plurality of banks BANK0-15, each bank including a plurality of word lines WL, a plurality of bit lines BL, and a plurality of memory cells MC arranged at intersections of the plurality of word lines WL and the plurality of bit lines BL. Although sixteen banks are shown in FIG. 2, memory array 250 may include any number of banks. The selection of the word line WL is performed by a row decoder 240 and the selection of the bit line BL is performed by a column decoder 245. Sense amplifiers (SAMP) are located for their corresponding bit lines BL and connected to at least one respective local I/O line pair (LIOT/B), which is in turn coupled to at least respective one main I/O line pair (MIOT/B), via transfer gates (TG), which function as switches. The TG may be coupled to one or more read/write amplifiers (RWAMP) 255, which may be coupled to an error correction code (ECC) circuit 235. The ECC circuit 235 may be coupled to an IO circuit 260, which may be coupled to one or more external terminals of memory device 200. Read data from the bit line BL is amplified by the sense amplifier SAMP, and transferred to read/write amplifiers 255 over complementary local data lines (LIOT/B), transfer gate (TG), and complementary main data lines (MIOT/B) to the ECC circuit 235. Conversely, write data outputted from the ECC circuit 235 is transferred to the sense amplifier SAMP over the complementary main data lines MIOT/B, the transfer gate TG, and the complementary local data lines LIOT/B, and written in the memory cell MC coupled to the bit line BL.

The memory device 200 may employ a plurality of external terminals that include command and address terminals coupled to a command/address (C/A) bus to receive command and address signals, clock terminals to receive clock signals CK_t and CK_c, data terminals DQ, RDQS, and power supply terminals VDD, VSS, VDDQ, and VSSQ.

The C/A terminals may be supplied with an address and a bank address signal from outside, for example, from a controller 202. The address signal and the bank address signal supplied to the address terminals are transferred, via a command/address input circuit 205, to an address decoder 212. The address decoder 212 receives the address signals and supplies a decoded row address signal XADD to the row decoder 240, and a decoded column address signal YADD to the column decoder 245. The address decoder 212 also receives the bank address signal BADD and supplies the bank address signal to the row decoder 240 and the column decoder 245.

The C/A terminals may further be supplied with command signals from, for example, a controller 202. In some embodiments, controller 202 may be implemented or included in controller 106. The command signals may be provided as internal command signals ICMD to a command decoder 215 via the command/address input circuit 205. The command decoder 215 includes circuits to decode the internal command signals ICMD to generate various internal signals and commands for performing operations, for example, a row activation signal (ACT) to select a word line. Another example may be providing internal signals to enable circuits for performing operations, such as control signals to enable signal input buffers that receive clock signals.

Each bank BANK0-15 may be organized into multiple physical column planes (CP). Each column plane may be associated with multiple column selects (e.g., CS0-63, CS0-59, CS0-55). In some embodiments, different column planes may be used to store different types of information. For example, some column planes may store data and another plane stores ECC data. A further plane may store GCR data. According to embodiments of the present disclosure, the array 250 can be selectively configured to utilize one or more column planes to store metadata.

The C/A terminals may receive an access command which is a read command. When a read command is received, and a bank address, a row address and a column address are timely supplied with the read command, a codeword including read data, metadata, and read ECC data (e.g., parity bits) is read from memory cells in the memory array 250 corresponding to the row address and column address. The read command is received by the command decoder 215, which provides internal commands so that read data from the memory array 250 is provided to the ECC circuit 235. The ECC circuit 235 may use the parity bits in the codeword to determine if the codeword includes any errors, and if any errors are detected, may correct them to generate a corrected codeword (e.g., by changing a state of the identified bit(s) which are in error). The corrected codeword (without the parity bits) is output from the data terminals DQ via the input/output circuit 260.

The C/A terminals may receive an access command which is a write command. When the write command is received, and a bank address, a row address, and a column address are timely supplied as part of the write operation, and write data is supplied through the DQ terminals to the ECC circuit 235. The write data (which may include write data and metadata) supplied to the data terminals DQ is written to a memory cells in the memory array 250 corresponding to the row address and column address. The write command is received by the command decoder 215, which provides internal commands so that the write data is received by data receivers in the input/output circuit 260. The write data is supplied via the input/output circuit 260 to the ECC circuit 235. The ECC circuit 235 may generate ECC data (e.g., a number of parity bits) based on the write data, and the write data and the parity bits may be provided as a codeword to the memory array 250 to be written into the memory cells MC.

The ECC circuit 235 may be used to ensure the fidelity of the data read from a particular group of memory cells to the data written to that group of memory cells. The memory device 200 may include a number of different ECC circuits 235, each of which is responsible for a different portion of the memory cells MC of the memory array 250. For example, there may be one or more ECC circuits 235 for each bank of the memory array 250. Typically, each bank BANK0-15 includes a column plane for the storage of ECC data (e.g., parity bits) and additional column planes for the storage of data (e.g., sixteen column planes). In these applications, the ECC circuit 235 generates eight bits of ECC data (e.g., 8 bits of ECC data) for each prefetch of 128 bits. This may allow for the ECC circuit 235 to provide single bit error correction.

The command decoder 215 may access mode register 275 that is programmed with information for setting various modes and features of operation for the memory device 200. For example, the mode register 275 may provide parameters that allow the memory device 200 to operate at different frequencies, provide different burst lengths, different storage modes, operate in x4, x8, or x16 mode, and/or other different operating conditions. In some embodiments, mode register 275 may include multiple registers.

The information in the mode register 275 may be programmed by providing the memory device 200 a mode register write command, which causes the memory device 200 to perform a mode register write operation. In some embodiments, data to be written to the mode register 275 is provided via the C/A terminals and/or the DQ terminals. The command decoder 215 accesses the mode register 275, and based on the programmed information along with the internal command signals provides the internal signals to control the circuits of the memory device 200 accordingly. Information programmed in the mode register 275 may be externally provided by the memory device 200 using a mode register read command, which causes the memory device 200 to access the mode register 275 and provide the programmed information (e.g., to the memory controller 202). In some embodiments, the information may be provided via the C/A terminals and/or the DQ terminals.

The mode register 275 may be programmed with a value that determines an amount of metadata stored in the memory device 200 (e.g., storage mode). When one value is stored in the register, no metadata may be stored (e.g., an operating mode where metadata is disabled). When another value is stored in the register, an amount of metadata may be stored, and when a further value is stored in the register, a different amount of metadata may be stored (e.g., operating modes where metadata is enabled). For example, the memory device 200 may have a mode where 16 bits of metadata are stored per prefetch (MD16 ON), a mode where 8 bits of metadata are stored per prefetch (MD8 ON), and a mode where no metadata is stored (MD OFF). The default mode may be MD16 ON in some embodiments. While the examples provided herein describe three storage modes with MD16 ON as the default mode, in other embodiments, the memory device 200 may include more or fewer storage modes, and/or a different storage mode may be the default storage mode.

Based on the values stored in the mode register 275, the mode register may provide one or more signals to the column decoder 245. In some embodiments, the signals from the mode register 275 may enable or disable one or more decoder circuits (or one or more components thereof). The decoder circuits may determine which column select signals are activated and/or physical column planes are accessed during an access operation (e.g., read or write operations). Selectively activating or suppressing column select signals associated with one or more physical column planes may allow the formation of virtual column planes. This may allow the memory device 200 to appear to the controller 202 to have a number of column planes different than a number of physical column planes in the array 250. Examples of a suitable suppression scheme may be found in U.S. patent application Ser. Nos. 18/916,497 and 18/916,521 filed Oct. 15, 2024, which are incorporated herein by reference for any purpose.

According to embodiments of the present disclosure, the mode register 275 may provide a signal MDMode indicating the storage mode of memory device 200 to the column decoder 245. The column decoder 245 may include remapping circuitry that selectively remaps certain column addresses based on the MDMode signal and the column address YADD.

According to embodiments of the present disclosure, the memory device 200 may include data steering circuitry 280. The data steering circuitry 280 may also receive the column address YADD and MDMode signal. Based on the YADD and MDMode signals, the data steering circuitry 280 may selectively steer data to and from target column planes.

Turning to the explanation of the external terminals included in the memory device 200, the clock terminals and data clock terminals are supplied with external clock signals and complementary external clock signals. The external clock signals CK_t, CK_c may be supplied to a clock input circuit 220. When enabled, input buffers included in the clock input circuit 220 pass the external clock signals. For example, an input buffer passes the CK_t and CK_c signals when enabled by a CKE signal from the command decoder 215. The clock input circuit 220 may use the external clock signals passed by the enabled input buffers to generate internal clock signal ICK. The internal clock signal ICK are supplied to internal clock circuit 230 for providing one or more clock signals to the various components of memory device 200.

The internal clock circuits 230 includes circuits that provide various phase and frequency controlled internal clock signals based on the received internal clock signals. For example, the internal clock circuits 230 may include a clock path (not shown in FIG. 2) that receives the ICK clock signal and provides internal clock signals ICK and ICKD to the command decoder 215. Optionally, the input/output circuit 260 may include clock circuits and driver circuits for generating and providing the RDQS signal to a controller.

The power supply terminals are supplied with power supply potentials VDD and VSS. These power supply potentials VDD and VSS are supplied to an internal voltage generator circuit 270. The internal voltage generator circuit 270 generates various internal potentials VPP, VOD, VARY, VPERI, and the like and a reference potential ZQVREF based on the power supply potentials VDD and VSS. The internal potential VPP is mainly used in the row decoder 240, the internal potentials VOD and VARY are mainly used in the sense amplifiers included in the memory array 250, and the internal potential VPERI is used in many other circuit blocks.

The power supply terminal is also supplied with power supply potential VDDQ. The power supply potentials VDDQ is supplied to the input/output circuit 260 together with the power supply potential VSS. The power supply potential VDDQ may be the same potential as the power supply potential VDD in an embodiment of the disclosure. The power supply potential VDDQ may be a different potential from the power supply potential VDD in another embodiment of the disclosure. However, the dedicated power supply potential VDDQ is used for the input/output circuit 260 so that power supply noise generated by the input/output circuit 260 does not propagate to the other circuit blocks.

FIG. 2 is a block diagram, and the blocks may not represent the relative size or locations of the various components. For example, the column decoder 245 may include multiple circuit components located in different parts of the memory device 200 (e.g., a portion closer to the address decoder 212 and a portion closer to the memory array 250. In another example, the data steering circuitry 280 may be located between the memory array 250 and the read/write amplifiers 255.

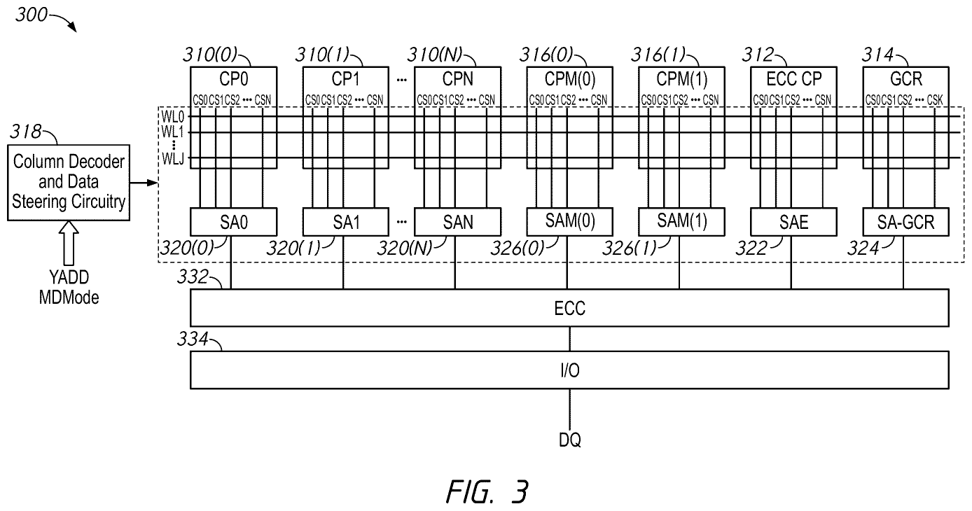

FIG. 3 is a block diagram of a portion of a memory device according to some embodiments of the present disclosure. The memory device 300 may, in some embodiments, represent a portion of the memory device 200 of FIG. 2 and/or a portion of one or more of the memory devices 104 in FIG. 1. FIG. 3 shows a portion of a memory array 310-316 and 320-326 which may be part of a memory bank (e.g., BANK0-15 of FIG. 2) along with selected circuits used in the data path such as the ECC circuit 332 (e.g., 235 of FIG. 2) and IO circuits 334 (e.g., 260 of FIG. 2). A block representing circuitry associated with the column decoder and data steering circuitry 318 is also shown. The column decoder and data steering circuitry 318 may include column decoder 245 and data steering circuitry 280. For clarity certain circuits and signals have been omitted from the view of FIG. 3.

The memory bank of a memory array of memory device 300 is organized into a number of column planes 310-316. Each column plane 310-316 includes a number of memory cells at the intersection of word lines WL and bit lines. The bit lines may be grouped together into sets which are activated by a value of a column select (CS) signal. For the sake of clarity, only a single vertical line is used to represent the bit lines of each column select set, however, there may be multiple bit lines accessed by that value of CS. For example, each line may represent eight bit lines, all accessed in common by a value of CS. As used herein, a ‘value’ of CS may refer to a decoded signal provided to sets of bit lines (e.g., from a column decoder). A first value may represent a first value of a multibit CS signal, or after decoding a signal line associated with that value being active. The word lines may be extended across multiple of the column planes 310-316.

The memory device 300 includes a set of column planes 310 that store data and column planes 316 that store metadata. The memory device 300 may include an ECC column plane 312 to store ECC information, such as error correction parity bits. The memory device 300 may also include an optional global column redundancy (GCR) column plane 314. In some embodiments, the GCR column plane 314 may have fewer memory cells (e.g., fewer column select groups) than the data column planes 310. The GCR CP 314 includes a number of redundant columns which may be used as part of a repair operation. If a value of the CS signal is identified as including defective memory cells in one of the data column planes 310, then the memory may be remapped such that the data which would have been stored in that column plane for that value of CS is instead stored in the GCR CP 314.

In the example shown in FIG. 3, the memory device 300 may include 16 data column planes 310(0)-310(15) and two metadata column planes 316(0)-316(1). Fourteen of the data column planes 310 each include 56 sets of column selects activated by a value of the column select signal and two of the data column planes 310 each include 60 sets of column selects activated by a value of the column select signal. Each of the metadata column planes 316 include 60 sets of column selects activated by a value of the column select signal. Thus, there is a total of 1024 column selects for the memory bank. Each set of column select includes 8 bit lines.

The memory device 300 may be set to be in a storage mode where both metadata planes 316 are utilized for storing metadata. In some embodiments, this may be a default storage mode for memory device 300. The storage mode may be set by writing a value to a mode register, such as mode register 275. when a word line is opened responsive to a row address, and a column select signal is provided to each of the 18 column planes then 8 bits are accessed from each of the 18 column planes for a total of 144 bits (128 data bits and 16 metadata bits). A column select signal is also provided to the ECC column plane 312, although that column select signal may be a different value than the one provided to the column planes 310 for an additional 8 bits. If a repair has been performed, the GCR CP 314 may also be accessed and the data from the GCR CP314 may be received instead of data from the originally indicated column plane. Accordingly, the maximum number of bits that can be retrieved as part of an access pass is 128 bits from the data column planes 310 (with 8 bits substituted from the GCR CP 314 if there has been a repair) along with 16 bits from the metadata column planes 316 and 8 additional bits from the ECC CP 312.

During read operations, data may be provided from the column planes 310 to the sense amplifiers 320 to the ECC circuit 332. Metadata may be provided from column planes 316 to sense amplifiers 326 and ECC data may be provided from column plane 312 to sense amplifier 322 to the ECC circuit 332. (If a repair has been made, data may also be provided from column plane 314 to sense amplifier 324 to the ECC circuit 332.) The ECC circuit 332 may use the ECC data provided from column plane 312 to correct and/or detect errors in the data and/or metadata. The ECC circuit 332 may output the data and metadata (corrected, if needed) to the I/O circuit 334. The I/O circuit 334 may provide the data and metadata to the DQ. The DQ may make the data and metadata available to an external device (e.g., a controller such as 106 in FIGS. 1 and/or 202 in FIG. 2). Optionally, the ECC circuit 332 may further provide error information for output on the DQ.

During write operations, data and metadata may be received by the I/O circuit 334 from the DQ and provide the data and metadata to the ECC circuit 332. Optionally, error information may also be received and provided to the ECC circuit 332. The ECC circuit 332 may generate parity bits and/or other error correction information for the data and metadata. The ECC circuit 332 may provide the data to sense amplifiers 320 for storage in column planes 310. Metadata may be provided to sense amplifiers 326 for storage in column planes 316 and the error correction information may be provided to sense amplifier 322 for storage in column plane 312. (If a repair has been made, data may also be provided from the ECC circuit 332 to sense amplifier 324 for storage in column plane 314.)

In the default storage mode, no data steering may occur (except between a column plane and the GCR 314 when a repair has been made). Further, the column addresses may correspond to the physical addresses of the column selects of the physical planes. Thus, no remapping of column address may occur in the default mode.

When the memory device 300 is in an operating mode that uses only one of the metadata planes 316 to store metadata, the other one of the metadata planes 316 may be used to store data instead of metadata. The activation of the column selects may be modified to form virtual planes from the column planes 310 and one of the metadata planes 316. When the memory device 300, is in an operating mode where the memory device 300 does not store metadata, the activation of the column selects may be modified to form virtual planes from column planes 310 and both metadata planes 316. The virtual planes may be associated with 64 column selects.

In these non-default storage modes, a first portion of the data associated with a virtual plane (e.g., VP3) may be stored in a first physical plane (e.g., CP3), and a second portion of the data associated with the virtual plane may be stored in a second physical plane (e.g., CPM0). According to embodiments of the present disclosure, in these storage modes, during a write operation, data steering circuitry 318 may steer the second portion of the data to the second physical plane. Similarly, during a read operation, data steering circuitry 318 may allow the second portion of the data to be retrieved from the second physical plane.

Further, in the non-default storage modes, because data for a single virtual plane is stored in multiple physical planes, the activation of column selects of certain column planes may need to be suppressed during access operations. However, because each virtual plane is associated with more column select signals (e.g., 64 CS) than the physical planes (e.g., 56 or 60), the column selects of the physical planes are utilized for reading and writing data associated with the virtual planes. According to embodiments of the present disclosure, in these non-default storage modes, the column decoder 318 may remap the column addresses such that not all of the column addresses correspond to the physical column select addresses.

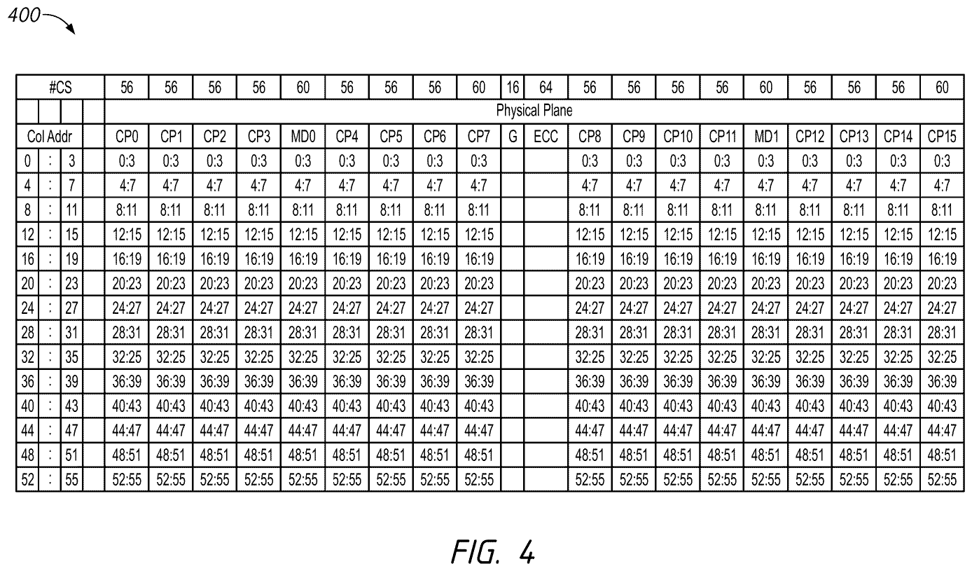

FIG. 4 shows a table indicating organization of a bank of a memory array according to some embodiments of the present disclosure. The organization depicted in table 400 may be used when a memory device (e.g., one or more of memory devices 104, memory device 200, and/or memory device 300) is in an operating mode where two column planes are utilized to store metadata. In some embodiments, 16 bits of metadata may be stored per prefetch (MD16 ON). In some embodiments, 8 bits for each prefetch may be stored in each of the metadata planes. In some embodiments, this may be a default storage mode for the memory device.

The top row indicates the number of column selects (#CS) associated with each physical plane. The two rows below indicates the physical column planes (CP0-15, MD0-1, G, and ECC). There are a total of 1,024 CS for data and metadata column planes. In the example shown in FIGS. 4, 56 CS are associated with data CP0-6 and CP8-14 and 60 CS are associated data CP7 and CP15. In other examples, different column planes may be assigned 60 CS instead of CP7 and/or CP15. Sixty CS are also associated with metadata planes MD0 and MD1. Sixty-four CS are associated with the ECC data plane ECC, and 16 CS are associated with the global column redundancy plane G.

Below the top three rows are several columns providing more details on the organization of the data in the memory array. The first column indicates the column address (ColAddr) for the column selects (CS). The remaining columns of table 400 indicate the physical column select signals (CS) of the physical column planes associated with the ColAddr.

In the operation mode where two column planes are utilized for metadata, the memory device operates in a manner where all data types (e.g., data, metadata, ECC data) are stored in the physical array they are associated with, and virtual planes are not used. This is indicated by all of the columns indicating that all of the CS signals are associated with data for the column plane in which they are located, and all of the physical addresses correspond to the ColAddr. Accordingly, no data steering or column address remapping occurs.

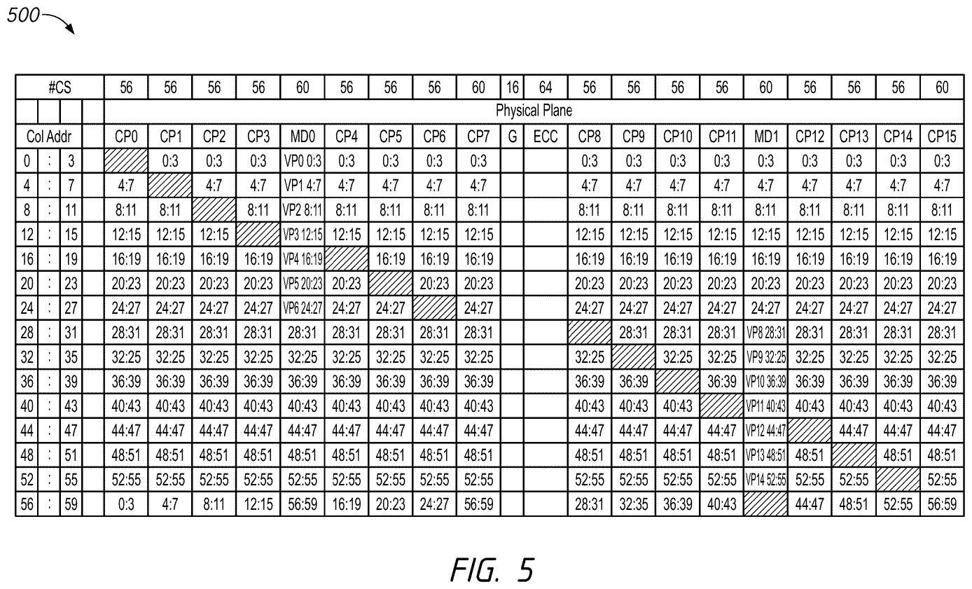

FIG. 5 shows a table indicating organization of the bank of the memory array and physical column plane suppression scheme according to some embodiments of the present disclosure. The organization depicted in table 500 may be used when a memory device (e.g., one or more of memory devices 104, memory device 200, and/or memory device 300) is in an operating mode where one column plane is utilized to store metadata. In some embodiments, 8 bits of metadata may be stored per prefetch (MD8 ON). The first three rows in table 500 are the same as table 400. The first column of table 500 is also the same as table 400 except that now there are column addresses for column selects 56:59.

When less metadata is stored (e.g., 8 bits instead of 16 bits) in the memory device, more space in the memory array is available for storing data. However, because of the allocation of the column selects, additional data cannot be stored in the physical data column planes. Rather, the additional data is stored in one of the metadata planes. To store the additional data, and for a controller (e.g., controller 106, controller 202) to receive the amount of data and metadata expected (e.g., 128 data bits and 8 metadata bits), the activation of the column selects are adjusted to form the 16 virtual data planes (virtual planes, VP0-15) each associated with 60 CS. In the example shown in FIG. 5, the additional data is stored in MD0 and MD1. The physical planes CP0-15 store data associated with the same numbered virtual planes VP0-15. In other words, CP0 stores data associated with VP0, CP1 stores data associated with VP1, CP2 stores data associated with VP2, and so on. In the example shown in FIG. 5, MD0 stores additional data for VP0-6, and MD1 stores additional data for VP8-14. Because the example implementation provides CP7 and CP15 with 60 column selects, the metadata planes MD0-MD1 do not store data associated with VP7 and VP15.

During operation, the column select signals for one or more physical column planes may be suppressed in order to output the expected amount of data (e.g., 128 bits) from the virtual planes. In the example shown in FIG. 5, column selects associated with one physical plane may be suppressed to prevent the memory from providing extra bits of data. When activation of one or more column selects of a column plane are suppressed, it may be referred to as suppressing the column plane.

The shaded boxes in table 500 indicate the column selects of a physical plane that are suppressed during a memory access operation. For example, say the column address 0:3 is provided. For virtual plane VP0, the data associated with column address 0:3 is located in MD0, not in physical plane CP0. Accordingly, CS0, CS1, CS2, and CS3 of physical plane CP0 is suppressed for the column address 0:3. In another example, say column address 52:55 is provided. For virtual plane VP14, the data associated with column address 52:55 is located in MD1, not in physical plane CP14. Accordingly, CS52, CS53, CS54, and CS55 of physical plane CP14 is suppressed for column address 52:55.

According to embodiments of the present disclosure, data steering circuitry may allow data associated with a virtual plane to be rerouted to and from the appropriate metadata plane. For example, during a write operation, data received from a controller and associated with column address 0:3 of VP0 may be steered to CS0:3 of MD0 by the data steering circuitry. Similarly, during a read operation, data from CS0:3 of MD0 may be steered to be associated with column address 0:3 to allow the controller to receive all of the data associated with VP0.

To avoid losing addressable array space, data for the virtual planes is stored in the locations associated with the suppressed column selects of the physical planes. The column addresses of the suppressed column selects are remapped to column addresses 56:59. Thus in contrast to FIG. 4, in the embodiment shown in FIG. 5, not all of the physical addresses of the column selects match the column addresses. For example, returning to virtual plane VP0, when column address 0:3 is provided, data is provided from CS0-3 of MD0. However, when column address 56:59 is provided, data from CS0:3 of physical CP0 is provided for virtual plane VP0. In another example, when column address 52:55 is activated, data from M1 is provided for virtual VP14, and when column address 56:59 are activated, data from CS52:55 of physical CP14 is provided for virtual plane VP14.

According to embodiments of the present disclosure, the remapping may be performed by a column decoder. The column decoder may receive the column address and an indication of the storage mode (e.g., from a mode register). Based on the column address and storage mode, the column decoder may selectively remap column addresses to the physical addresses of the column selects (e.g., column address 56:59 to CS4:7 for CP1).

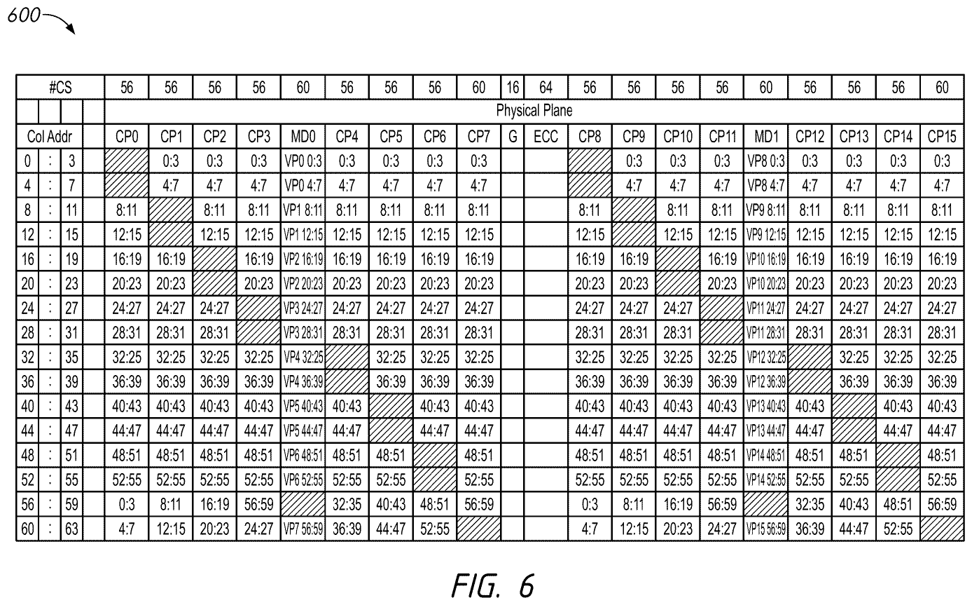

FIG. 6 shows a table indicating organization of the bank of the memory array and physical column plane suppression scheme according to some embodiments of the present disclosure. The organization depicted in table 500 may be used when a memory device (e.g., one or more of memory devices 104, memory device 200, and/or memory device 300) is in an operating mode where no metadata is stored (MD OFF). The first three rows in table 600 are the same as table 400 and table 500. The first column of table 600 is also the same as table 400 and table 500.

When no metadata is stored in the memory device, more space in the memory array is available for storing data. Similar to the example provided in FIG. 5, the additional data for a virtual plane is stored in one of the metadata planes. Further, the activation of the column selects are adjusted to form the 16 virtual data planes (virtual planes, VP0-15) each associated with 64 CS (instead of 60 CS as in FIG. 5). In the example shown in FIG. 6, the physical planes CP0-15 store data associated with the same numbered virtual planes VP0-15. Similar to FIG. 5, CP0 stores data associated with VP0, CP1 stores data associated with VP1, CP2 stores data associated with VP2, and so on. MD0 stores additional data for VP0-7, and MD1 stores additional data for VP8-15. Because the example implementation provides CP7 and CP15 with 60 column selects, the metadata planes MD0-MD1 store less data associated with VP7 and VP15 compared to VP0-6 and VP8-14.

During operation, the column select signals for one or more physical column planes may be suppressed in order to output the expected amount of data (e.g., 128 bits) from the virtual planes. In the example shown in FIG. 6, column selects associated with one or two physical planes may be suppressed to prevent the memory from providing extra bits of data.

The shaded boxes in table 600 indicate the column selects of a physical plane that are suppressed during a memory access operation. For example, say the column address 0:7 is provided. For virtual plane VP0, the data associated with column address 0:7 is located in MD0, not in physical plane CP0. Accordingly, CS0-CS7 of physical plane CP0 is suppressed for the column address 0:7. In another example, say column address 48:55 is provided. For virtual plane VP14, the data associated with column address 48:55 is located in MD1, not in physical plane CP14. Accordingly, CS48-55 of physical plane CP14 is suppressed for column address 48:55.

According to embodiments of the present disclosure, similar to FIG. 5, data steering circuitry may allow data associated with a virtual plane to be rerouted to and from the appropriate metadata plane. For example, during a write operation, data received from a controller and associated with column address 0:7 of VP0 may be steered to CS0:7 of MD0 by the data steering circuitry. Similarly, during a read operation, data from CS0:7 of MD0 may be steered to be associated with column address 0:7 to allow the controller to receive all of the data associated with VP0.

To avoid losing addressable array space, data for the virtual planes is stored in the locations associated with the suppressed column selects of the physical planes. The column addresses of the suppressed column selects are remapped to column address 56:59 or 56:63. Thus similar to FIG. 5, not all of the physical addresses of the column selects match the column addresses. For example, returning to virtual plane VP0, when column address 0:7 is provided, data is provided from CS0-7 of MD0. However, when column address 56:59 is provided, data from CS0:3 of physical CP0 is provided for virtual plane VP0, and when column address 60:63 is provided data from CS4:7 of physical CP0 is provided. In another example, when column address 48:55 is activated, data from M1 is provided for virtual VP14, and when column address 56:63 are activated, data from CS48:55 of physical CP14 is provided for virtual plane VP14.

In contrast to FIG. 5, even the metadata planes MD0 and MD1 have suppressed column planes and address remapping. For example, since CP7 has 60 CS, MD0 stores 8 bits of data for VP7 compared to 16 bits of data for VP0-6. Accordingly, MD01 is suppressed when column address 56:59 is provided. However, when column address 60:63 is provided, MD0 provides data for virtual plane VP7 from CS56:59. A similar suppression and remapping occurs for MD1 and CP15 for virtual plane VP15.

According to embodiments of the present disclosure, the remapping may be performed by a column decoder. The column decoder may receive the column address and an indication of the storage mode (e.g., from a mode register). Based on the column address and storage mode, the column decoder may selectively remap column addresses to the physical addresses of the column selects (e.g., column address 56:59 to CS4:7 for CP1).

FIGS. 5 and 6 provide example implementations of arranging the physical column planes into virtual planes. Other arrangements may also be used. For example, data for the virtual planes may be stored across the physical column planes different, the pattern of suppression may be different, and/or the remapping of column addresses to physical column selects may be different.

In some embodiments, such as the ones shown in FIGS. 5 and 6, storing data for virtual planes VP0-7 on one side of the bank (e.g., physical planes CP0-7 and MD0) and storing data for virtual planes VP8-15 on the other side of the bank (e.g., physical planes CP8-15 and MD1) may reduce the number and/or length of conductive traces and/or number of circuit components required for data steering.

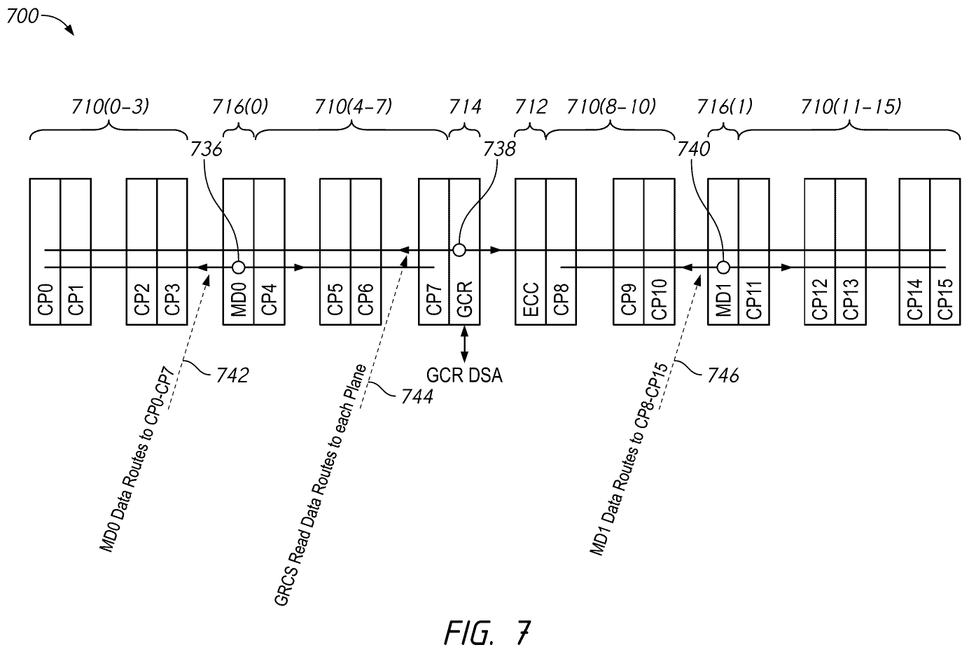

FIG. 7 includes a block diagram of a portion of a memory device according to some embodiments of the present disclosure. Memory device 700 may be included as a portion of one or more of memory devices 104 in FIG. 1, memory device 200 in FIG. 2, and/or memory device 300 in FIG. 3. In some embodiments, memory device 700 may have an array with memory banks arranged as described in FIGS. 4-6. FIG. 7 illustrates a read path of the memory device 700.

Memory device 700 may include a memory bank arranged into multiple physical column planes 710-716. Column planes 710(0-15) may store data. Depending on the selected storage mode, column planes 716(0-1) may store metadata and/or data. The ECC plane 712 may store error correction data (e.g., parity bits), and the GCR plane 714 may include additional column selects used to replace defective column selects in the other column planes.

The memory device 700 may include conductive traces 742, 744, and 746 (e.g., wires, metalization lines) for steering data to and from the column planes. The conductive trace 744 may be coupled to column planes 710(0-15), 716(0-1), 712, and the GCR plane 714. If a column plane has been repaired, during read operations, data from the GCR plane 714 may provide data to column planes 710(0-15) 716(0-1), 712 as indicated by circle 738. This may allow data to be steered from the GCR plane 714 and any column planes 710(0-15) 716(0-1), 712 that have had one or more column selects repaired. Data from the GCR plane may be received by the data sense amplifiers and/or IO lines of the repaired column plane. Thus, the data “appears” to be provided by the column plane that has been repaired.

Conductive trace 742 may be coupled to column planes 710(0-7) and to the metadata plane 716(0). During read operations, data from the metadata plane 716(0) may be provided to the conductive trace 742 as indicated by circle 736. The data from metadata plane 716(0) may be steered to data planes 710(0-7) when the metadata plane 716(0) stores data (e.g., in a non-default storage mode). For example, data may be steered from the metadata plane 716(0) when the memory device 700 is in the storage mode shown in FIG. 5 or the storage mode shown in FIG. 6. When data from virtual plane VP0-7 is requested by a read command, the corresponding data plane 710(0-7) may provide the data, and data from metadata plane 716(0) may provide data to said data plane 710(0-7), which may be received by the data sense amplifiers and/or IO lines of the data plane 710(0-7). Thus, all of the data for a virtual plane appears to come from a single physical column plane.

Similarly, conductive trace 746 may be coupled to column planes 710(8-15) and to the metadata plane 716(1). During read operations, data from the metadata plane 716(1) may be provided to the conductive trace 746 as indicated by circle 740. The data from metadata plane 716(1) may be steered to data planes 710(8-15) when the metadata plane 716(1) stores data. When data from virtual plane VP8-15 is requested by a read command, the corresponding data plane 710(8-15) may provide the data, and data from metadata plane 716(1) may provide data to said data plane 710(8-15), which may be received by the data sense amplifiers and/or IO lines of the data plane 710(8-15). For example, if the memory device 700 receives a read command associated with virtual plane VP12, data from data column plane 710(12) (CP12) may be provided, and additional data from metadata plane 716(1) (MD1) may be steered along conductive trace 746 to data plane 710(12). For example, if memory device 700 is in the storage mode shown in FIG. 5, data from CS44:47 of metadata plane 716(1) may be steered to data plane 710(12).

While arrangements of data and metadata in a memory bank other than those shown in FIGS. 4-6 are possible, utilizing column planes located on different sides of the bank for metadata and utilizing a metadata column plane for storing data for data column planes on the same side of the memory bank allows for less additional metalization. For example, if metadata plane 716(0) stored data from data planes 710(8-15), additional conductive traces would be required and/or conductive trace 742 would have to extend the full length of the memory bank. Further, while conductive traces 742, 744, and 746 are shown and described as single conductive traces, conductive traces 742, 744, and/or 746 may include multiple conductive traces.

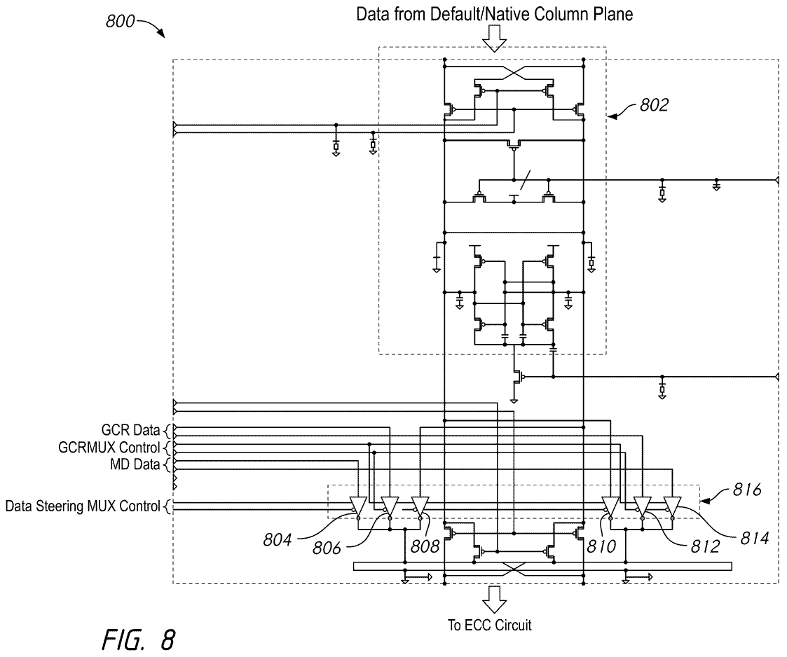

FIG. 8 is a circuit diagram of a portion of a memory device according to some embodiments of the present disclosure. Memory device 800 may be included as a portion of one or more of memory devices 104 in FIG. 1, memory device 200 in FIG. 2, memory device 300 in FIG. 3, and/or memory device 700 in FIG. 7. In some embodiments, memory device 800 may have an array (not shown) with memory banks arranged as described in FIGS. 4-7. The circuitry may be included in a read path of memory device 800. Memory device 800 may include a sense amplifier (SA) 802 that receives data from a physical column plane and data steering circuitry 816.

The data steering circuitry 816 includes multiplexers (muxes) 804-814. Muxes 806 and 812 may receive data from a GCR plane (e.g., GCR plane 714). Responsive to GCR MUX control signals, the muxes 806 and 812 may selectively provide data from the GCR plane to the ECC circuit (e.g., ECC circuit 332) during a read command. The GCR MUX control signals may cause the muxes 806 and 812 to pass the data from the GCR plane when the column select associated with the SA 802 is defective and has been replaced by a column select in the GCR plane. In these cases, data from the GCR plane is provided to the ECC circuit instead of from sense amplifier 802.

The sense amplifier 802 receives data from a default/native physical column plane (e.g., data column plane 710(0-15) in FIG. 7). When activated during a read command, the SA 802 may provide data from the physical column plane as a differential signal to data steering circuitry 816. The column plane data from the SA 802 may be received by muxes 808 and 814. Muxes 808 and 810 may receive data steering MUX control signals. The data steering mux control signals may be based, at least in part, on a storage mode of memory device 800 and a column address received associated with the read command. When activated by the data steering MUX control signals, muxes 808 and 810 may pass the data from the sense amplifier 802 to the ECC circuit.

For example, if SA 802 is associated with CS44:47 of physical CP12, when column address 44:47 is provided with the read command, the data steering MUX control signals may activate muxes 808 and 810 when memory device 800 is in the storage modes shown in FIG. 4 or FIG. 6. However, if the memory device 800 is in the storage mode shown in FIG. 5, the data steering MUX control signals may not activate muxes 808 and 810. Further, if the column select associated with SA 802 has been repaired using the GCR plane, the data steering MUX control signals may not activate muxes 808 and 810 regardless of the storage mode.

Muxes 804 and 814 may receive data from a metadata plane (e.g., metadata planes 716(0-1)). Responsive to data steering MUX control signals, the muxes 804 and 814 may selectively provide data from the metadata plane to the ECC circuit during a read command. For example, if SA 802 is associated with CS44:47 of physical CP12, when column address 44:47 is provided with the read command, the data steering MUX control signals may not activate muxes 804 and 814 when memory device 800 is in the storage modes shown in FIG. 4 or FIG. 6. Rather, for the storage mode shown in FIG. 4, data would come from CP 12 (the default/native column plane), and data from the metadata plane would be provided to the portion of the ECC circuit associated with the metadata plane. For the storage mode shown in FIG. 6, data would come from CP 12 (the default/native column plane), and data from the metadata plane would be steered to the portion of the ECC circuit associated with CP13. In contrast, when the memory device 800 is in the storage mode shown in FIG. 5, the data steering MUX control signals may activate muxes 804 and 814 to steer data from the metadata plane (MD1) to the ECC circuit.

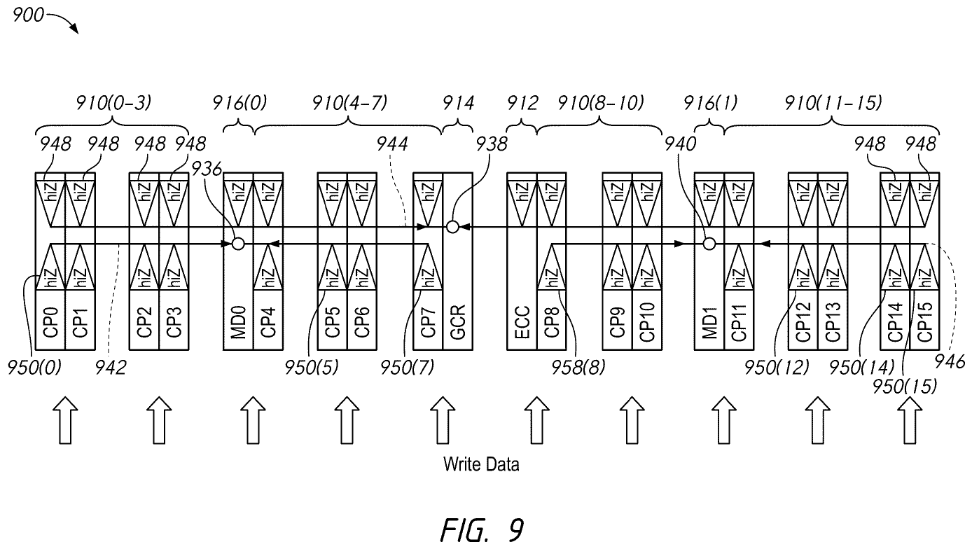

FIG. 9 is a block diagram of a portion of a memory device according to some embodiments of the present disclosure. Memory device 900 may be included as a portion of one or more of memory devices 104 in FIG. 1, memory device 200 in FIG. 2, memory device 300 in FIG. 3, memory device 700 in FIG. 7, and/or memory device 800 in FIG. 8. In some embodiments, memory device 900 may have an array with memory banks arranged as described in FIGS. 4-6. FIG. 9 illustrates a write path of the memory device 900.

Memory device 900 may include a memory bank arranged into multiple physical column planes 910-916. Column planes 910(0-15) may store data. Depending on the selected storage mode, column planes 916(0-1) may store metadata and/or data. The ECC plane 912 may store error correction data (e.g., parity bits), and the GCR plane 914 may include additional column selects used to replace defective column selects in the other column planes.

The memory device 900 may include conductive traces 942, 944, and 946 (e.g., wires, metalization lines) for steering data to and from the column planes. The conductive trace 944 may be coupled to column planes 910(0-15), 916(0-1), 912 and the GCR plane 914. During write operations, for a column plane that has been repaired, a tri-state driver 948 may be activated and drive data provided to the column plane on conductive trace 944 to provided data to the GCR plane 914 as indicated by circle 938. In some applications, the tri-state drivers 984 may be activated by control signals generated based at least in part on repair information.

Conductive trace 942 may be coupled to column planes 910(0-7) and to the metadata plane 916(0). During write operations, when memory device 900 is in a storage mode where the metadata plane 916(0) stores data (e.g., as shown in FIGS. 5 and 6), write data provided to a column plane 910(0-7) may be driven by an active tri-state driver 950(0-7) to the metadata plane 916(0) via conductive trace 942 as indicated by circle 936. The tri-state drivers 950(0-7) may be activated by control signals from data steering circuitry such as data steering circuitry 280 and/or data steering circuitry 318. Whether the tri-state drivers 950(0-7) are activated may be based on the storage mode and the column address associated with the write operation.

For example, when memory device 900 is in the storage mode shown in FIG. 5, when column address 12:15 is received for virtual column plane VP3, physical column plane CP3 is suppressed. Instead, the tri-state driver 950(3) is activated and data is driven on conductive trace 942 to metadata plane 916(0).

Similarly, conductive trace 946 may be coupled to column planes 910(8-15) and to the metadata plane 916(1). During write operations, when memory device 900 is in a storage mode where the metadata plane 916(1) stores data (e.g., as shown in FIGS. 5 and 6), write data provided to a column plane 910(8-15) may be driven by an active tri-state driver 950(8-15) to the metadata plane 916(1) via conductive trace 946 as indicated by circle 940. The tri-state drivers 950(8-15) may be activated by control signals from data steering circuitry such as data steering circuitry 280 and/or data steering circuitry 318 in a same or similar manner to tri-state drivers 950(0-7). While conductive traces 942, 944, and 946 are shown and described as single conductive traces, conductive traces 942, 944, and/or 946 may include multiple conductive traces.

As shown in FIG. 9, data may enter the write path in the native column plane independent of the column address. The input path is coupled to the metadata planes with tri-state drivers at each physical data column plane. When incoming data needs to be steered from the native data column plane (e.g., when the memory array is arranged into virtual planes), the tri-state drivers will be activated to provide data to the metadata plane. The data is written and stored in the metadata plane.

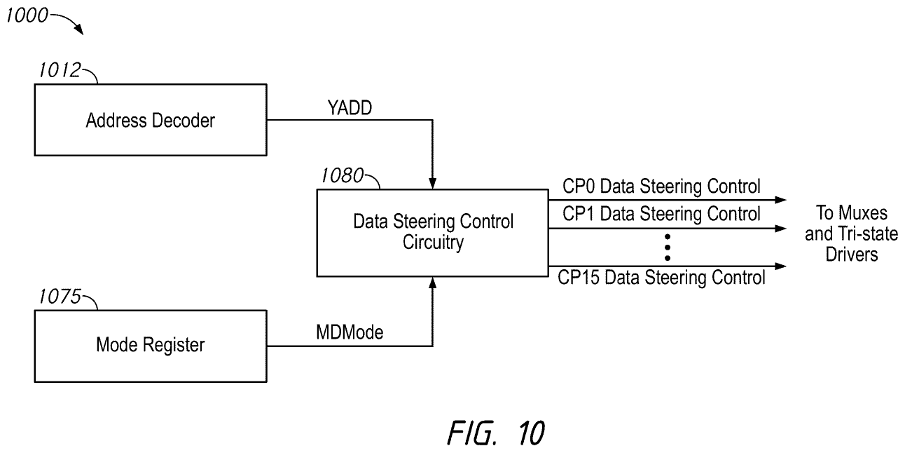

FIG. 10 is a block diagram of a portion of a memory device according to some embodiments of the present disclosure. Memory device 1000 may be included as a portion of one or more of memory devices 104 in FIG. 1, memory device 200 in FIG. 2, memory device 300 in FIG. 3, memory device 700 in FIG. 7, memory device 800 in FIG. 8, and/or memory device 900 in FIG. 9. In some embodiments, memory device 1000 may have an array (not shown) with memory banks arranged as described herein. Memory device 1000 may include an address decoder 1012, a mode register 1075, and data steering control circuitry 1080. In some embodiments, address decoder 1012 may be included in address decoder 212. In some embodiments, mode register 1075 may be included in mode register 275. In some embodiments, data steering control circuitry 1080 may be included in data steering circuitry 280 and/or data steering circuitry 318.

Data steering control circuitry 1080 may receive a column address YADD associated with an access operation (e.g., read command, write command) from the address decoder 1012. The data steering control circuitry 1080 may receive a storage mode signal MDMode which indicates of a storage mode from the mode register 1075. In some embodiments, MDMode may be a multi-bit signal. Based on the column address YADD and storage mode MDMode, the data steering control circuitry 1080 may output data steering control signals. The data steering control signals may be provided to additional data steering circuitry such as multiplexers 804, 808, 810, and 814 in FIG. 8 and/or tri-state drivers 950(0-15) in FIG. 9. In the embodiment shown in FIG. 10, the data steering control circuitry 1080 provides separate control signals for each column plane of the memory bank. In some embodiments, the data steering control circuitry 1080 may provide separate control signals for the read and write paths.

In some embodiments, data steering control circuitry 1080 may include one or more logic circuits that implements a look-up table. For example, the logic circuits may implement the tables provided in FIGS. 4-6. While in some applications, implementing a look-up table with logic circuits may require more layout than other schemes, the logic circuits may be located further away in a less congested area of the memory device 1000. Further, the look-up table-based control signals may reduce the number of additional conductive traces required to implement the data steering disclosed herein.

As described previously, when a memory device is organized according to the storage mode shown in FIG. 4, no data steering may be performed (except for repairs with GCR plane). Further, the logical column address shown on the left-hand side, matches the physical addresses for the physical column planes. Thus, no mapping between logical and physical addresses may be performed either. However, in the storage modes shown in FIGS. 5 and 6, while some of the logical and physical addresses still match. In these storage modes, the non-matching logical addresses are remapped to the physical addresses shown in tables 500 and 600. Thus, in addition to circuitry for physically steering data between physical column planes to accommodate the different storage modes (e.g., to provide the virtual column planes), the column decoder may include circuitry for remapping logical addresses (e.g., addresses for the virtual planes) to the physical addresses of the physical column planes for the different storage modes.

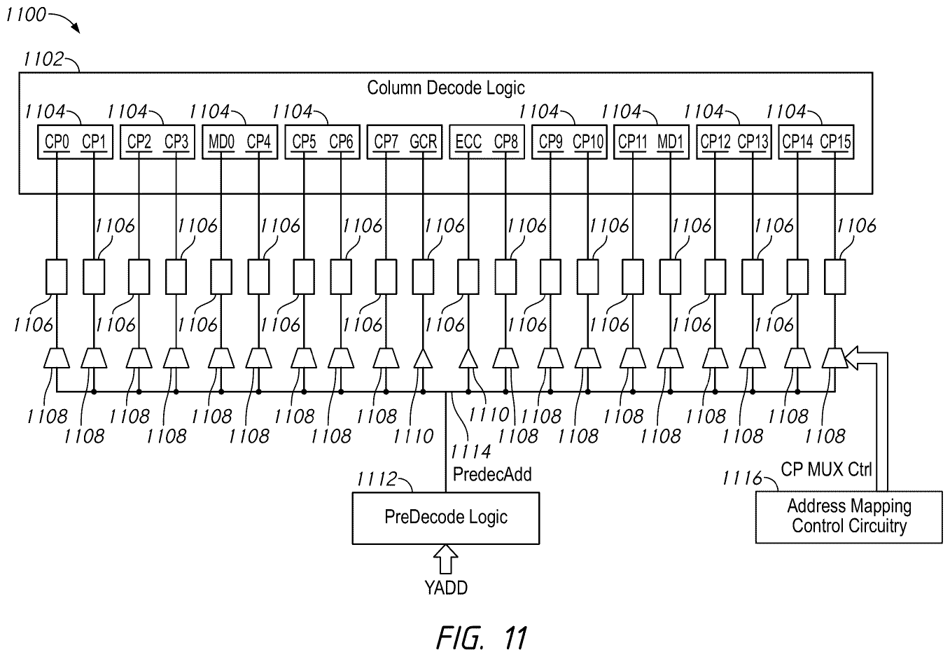

FIG. 11 is a block diagram of at least a portion of a column decoder according to some embodiments of the present disclosure. The column decoder 1100 may be included in column decoder 245 and/or column decoder 318 in some embodiments.

The column decoder 1100 may include predecode logic 1112 that receives a logical column address YADD from an address decoder, such as address decoder 212). Predecode logic 1112 may include one or more logic circuits that implements at least some decoding of the logical column address YADD.

As noted, when a memory device that includes column decoder 1100 is in a non-default storage mode (e.g., when data steering and/or address remapping is used), not all of the logical addresses require remapping. Many of the column selects of the physical planes match the logical addresses. Further, which logical addresses that are remapped vary by physical column plane.

According to embodiments of the present disclosure, the column decoder 1100 may include multiplexers (muxes) 1108 for the physical column planes that store data and/or metadata (e.g., CP0-15, MD0, and MD1). The muxes 1108 may receive predecoded addresses PredecAdd from the predecode logic 1112 via predecode bus 1114. The muxes 1108 may receive control signals (CP MUX Ctrl) from address mapping control circuitry 1116. The control signals may be based, at least in part, on the column address and the storage mode of the memory device. Based on the control signals, the muxes 1108 may provide the unmodified PredecAdd (e.g., native/default address) as an output or provide a remapped PredecAdd as the output. In the examples shown in FIGS. 4-6, a column address may be remapped by shifting the native address either four or eight places based on the storage mode and column address YADD. However, other remapping schemes may be used in other examples without departing from the principles of the present disclosure.

For example, if memory device is in the default storage mode (e.g., as shown in FIG. 4), all of the predecoded addresses may be passed unmodified by the muxes 1108. Certain muxes 1108 may provide unmodified predecoded addresses when the column address for the corresponding column plane is not remapped for the storage mode. For example, if the memory device is in the storage mode shown in FIG. 5, the mux 1108 associated with CP0 may provide unmodified predecoded addresses for logical addresses corresponding to CS4:55. However, the mux 1108 associated with CP may remap the logical addresses CS56:59 to physical address CS0:3. (Note that CP0 is suppressed for logical address 0:3, so no remapping occurs).

In some embodiments, remapping is not necessary for any of the storage modes for the ECC and GCR column planes. The predecode logic 1112 may provide the predecoded addresses to delays 1110 that output the unmodified predecoded addresses.

The remapped and/or unmodified predecoded addresses may be provided from the muxes 1108 and delays 1110 to drivers 1106. The drivers 1106 may drive the remapped and/or unmodified predecoded addresses to the column decode logic 1102. The column decode logic 1102 may include one or more logic circuits 1104 for decoding the predecoded addresses to the physical addresses for the column planes. The column decode logic 1102 may activate the column selects of the column planes indicated by YADD.

While predecode logic 1112 is shown as part of the column decoder 1100, in some embodiments, predecode logic 1112 may be included, at least in part, with the address decoder. Further, in some embodiments, the muxes 1108, delays 1110, and/or drivers 1106 may may be included, at least in part, with the address decoder.

By utilizing the muxes 1108 to selectively modify the predecode addresses, the physical column planes are able to share predecode logic 1112. This may reduce the size and/or complexity of the circuitry of column decoder 1100. Further, because individual drivers 1106 are utilized for providing the predecoded addresses for the individual column planes, the drivers 1106 may be smaller than when fewer drivers are utilized to drive the predecoded addresses to the column decode logic as in conventional column decoders. This may reduce the impact of the increased layout size of the drivers 1106 and/muxes 1108.

Alternatively, multiplexing may be applied to the column address YADD prior to predecoding by predecode logic 1112. However, this embodiment would require a separate predecode logic circuit for each column plane and may require less efficient routing.

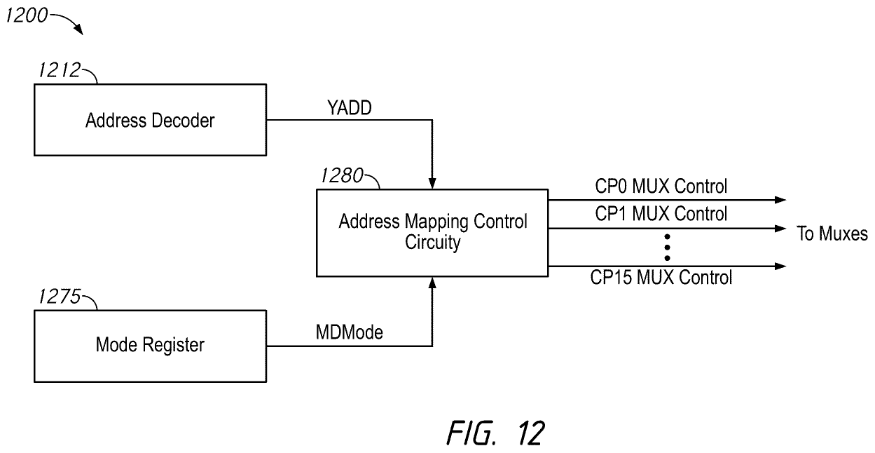

FIG. 12 is a block diagram of a portion of a memory device according to some embodiments of the present disclosure. Memory device 1200 may be included as a portion of one or more of memory devices 104 in FIG. 1, memory device 200 in FIG. 2, memory device 300 in FIG. 3, memory device 700 in FIG. 7, memory device 800 in FIG. 8, memory device 900 in FIG. 9, and/or memory device 1000 in FIG. 10. In some embodiments, memory device 1200 may have an array (not shown) with memory banks arranged as described herein. Memory device 1200 may include an address decoder 1212, a mode register 1275, and an address mapping control circuitry 1280. In some embodiments, address decoder 1212 may be included in address decoder 212. In some embodiments, mode register 1275 may be included in mode register 275. In some embodiments, address mapping control circuitry 1280 may be included in address mapping control circuitry 1116.

Address mapping control circuitry 1280 may receive a column address YADD associated with an access operation (e.g., read command, write command) from the address decoder 1212. The address mapping control circuitry 1280 may receive a storage mode signal MDMode which indicates of a storage mode from the mode register 1275. In some embodiments, MDMode may be a multi-bit signal. Based on the column address YADD and storage mode MDMode, the address mapping control circuitry 1280 may output address mapping control signals (CP0 MUX Control, CP1 MUX Control, etc.) to additional remapping circuitry such as multiplexers 1108 in FIG. 11. In the embodiment shown in FIG. 12, the address mapping control circuitry 1280 provides separate control signals for each column plane of the memory bank.

In some embodiments, address mapping control circuitry 1280 may include one or more logic circuits that implements a look-up table. For example, the logic circuits may implement the tables provided in FIGS. 4-6. While in some applications, implementing a look-up table with logic circuits may require more layout than other schemes, the logic circuits may be located further away in a less congested area of the memory device 1200. Further, the look-up table-based control signals may reduce the number of additional conductive traces required to implement the address remapping disclosed herein.

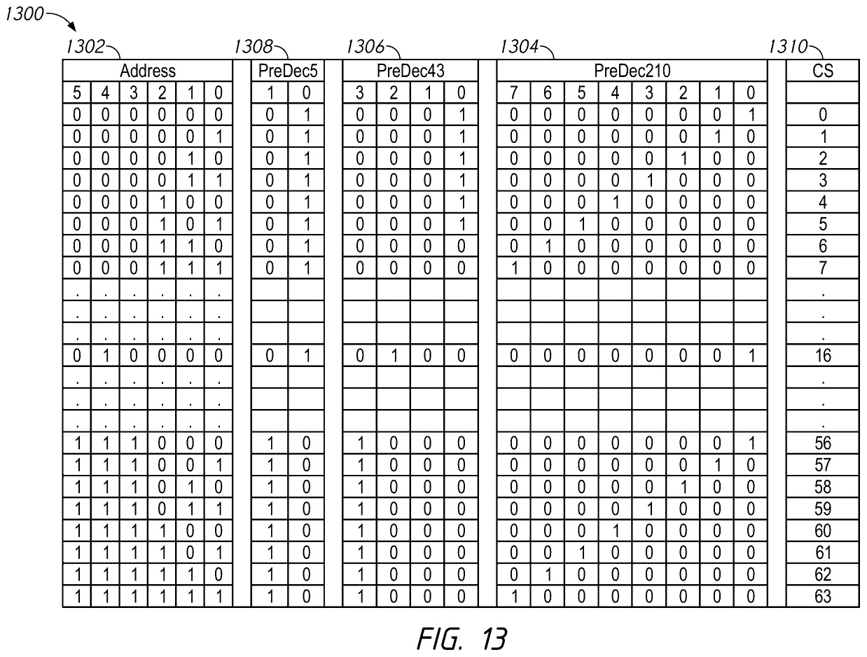

FIG. 13 shows a table of example decoding schemes according to some embodiments of the present disclosure. The decoding scheme shown in table 1300 may be implemented by any of the memory devices 104 in FIG. 1, memory device 200 in FIG. 2, memory device 300 in FIG. 3, memory device 700 in FIG. 7, memory device 800 in FIG. 8, memory device 900 in FIG. 9, memory device 1000 in FIG. 10, and/or memory device 1200 in FIG. 12. In some embodiments, the decoding scheme shown in table 1300 may be implemented at least in part by the column decoder 1100. The decoding scheme shown in table 1300 may implement the storage modes shown in FIGS. 4-6. However, other decoding schemes may be used, and the decoding scheme is provided merely as an example.

In the decoding scheme, the final column driver may use predecoded terms from six column addresses to reduce the number of transistors in the circuit. In the example in table 1300, the 2, 1, 0 bits of the column address 1302 may be logically combined to generate eight bits of predec210 1304. One of the bits in predecode210 1304 is asserted (e.g., ‘1’ in the example shown in FIG. 13) for a given column address 1302. The 4 and 3 bits of the column address 1302 may be logically combined to generate four bits of predec43 1306, and the 5 bit of the column address 1302 provide the state of the 5 bit of the column address 1302 as predec5. Thus, addresses corresponding to all of the column selects 0:63 may be generated by the predecode circuitry.

For example, in the “default” storage mode where 16 bits of metadata are stored (MD16 ON) as shown in FIG. 4, for physical column plane CP15, the terms connecting to the final column driver circuit are:
Col 0 PreDec5<0> PreDec43<0> PreDec210<0>
Col 1 PreDec5<0> PreDec43<0> PreDec210<1>
Col 2 PreDec5<0> PreDec43<0> PreDec210<2>
Col 3 PreDec5<0> PreDec43<0> PreDec210<3>

In the storage mode where 8 bits of metadata are stored (MD8 ON) as shown in FIG. 5, for physical column plane CP15, physical columns 0:3 are mapped to logical address 56:59. To accommodate this, the terms connecting to the final column driver are:
Col 0 PreDec5<1> PreDec43<3> PreDec210<0>
Col 1 PreDec5<1> PreDec43<3> PreDec210<1>
Col 2 PreDec5<1> PreDec43<3> PreDec210<2>
Col 3 PreDec5<1> PreDec43<3> PreDec210<3>

In this example, PreDec210 terms do not need to be remapped, but PreDec5<0> input to the final column driver is connected to PreDec5<1> and PreDec43<0> input to the final column driver is connected to PreDec43<3>. These connection changes may be accomplished with a column plane specific multiplexer that is controlled by the metadata mode and incoming column address, such as the multiplexers 1108 shown in FIG. 11. When column address is in the range of 56:59, the mux will swap the predecode terms going to the final column driver accordingly.

Other column planes will also have multiplexing controlled by control signals (e.g., as shown in FIGS. 11 and 12), but the address mapping may be different for the column planes. For example, physical column plane CP14 will have the following:
MD16 ON mode (FIG. 4):
Col 4 PreDec5<0> PreDec43<0> PreDec210<4>
Col 5 PreDec5<0> PreDec43<0> PreDec210<5>
Col 6 PreDec5<0> PreDec43<0> PreDec210<6>
Col 7 PreDec5<0> PreDec43<0> PreDec210<7>
MD8 ON mode (FIG. 5):
Col 4 PreDec5<1> PreDec43<3> PreDec210<4>
Col 5 PreDec5<1> PreDec43<3> PreDec210<5>
Col 6 PreDec5<1> PreDec43<3> PreDec210<6>
Col 7 PreDec5<1> PreDec43<3> PreDec210<7>

As illustrated in FIGS. 4 and 5, addressing physical column plane CP14 utilizes muxing of PreDec210 terms in addition to PreDec5 and PreDec43 terms. Each physical column plane may have a unique address muxing map depending on mode and incoming column address.

The specific implementation in this example utilizes muxing of the column addresses for the physical column planes for metadata (MD0 and MD1) when the storage mode where no metadata is stored (MD OFF) as shown in FIG. 6. However other implementations of the multiplexing and/or predecoding scheme may be used in other examples.

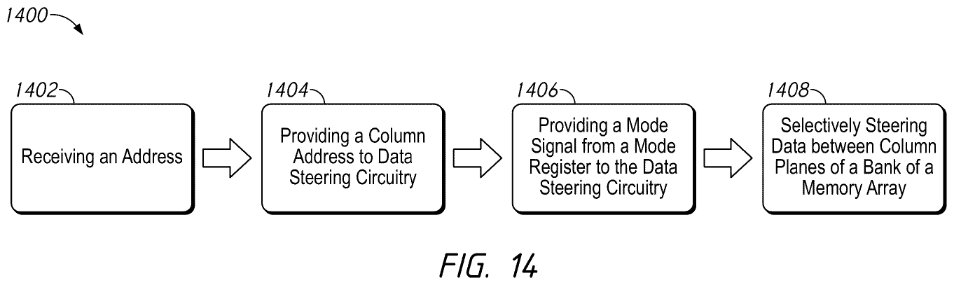

FIG. 14 is a flow chart of a method according to embodiments of the present disclosure. The method shown in flow chart 1400 may be performed in whole or in part by any of the memory devices disclosed herein.

At block 1402, “receiving an address” may be performed. The address may be received at a memory device. At block 1404, “providing a column address to data steering circuitry” may be performed. For example, address decoder 212 may provide the column address to data steering circuitry 280. At block 1406, “providing a mode signal from a mode register to the data steering circuitry” may be performed. For example, mode register 275 may provide a mode signal to data steering circuitry 280.

Responsive to the column address and the mode signal, at block 1408 “selectively steering data between column planes of a bank of a memory array” may be performed. For example, data may be steered in a manner to implement one of the arrangements shown in FIGS. 4-6. In some embodiments, the column address and the mode signal are provided to at least one logic circuit implementing a look-up table, for example, as shown in FIG. 10.

In some embodiments, the method shown in flow chart 1400 may further include receiving a read command associated with the address, wherein selectively steering comprises steering the data from a metadata column plane to a read path of a data column plane of the bank. In some embodiments, steering the data further includes activating a multiplexer. For example, as described with reference to FIGS. 7 and 8.

In some embodiments, the method shown in flow chart 1400 may further include receiving a write command associated with the address, wherein selectively steering comprises steering the data from a write path of a data column plane to a metadata column plane and writing the data to the metadata column plane. In some embodiments, steering the data further comprises activating a tri-state driver. For example, as described with reference to FIG. 9.

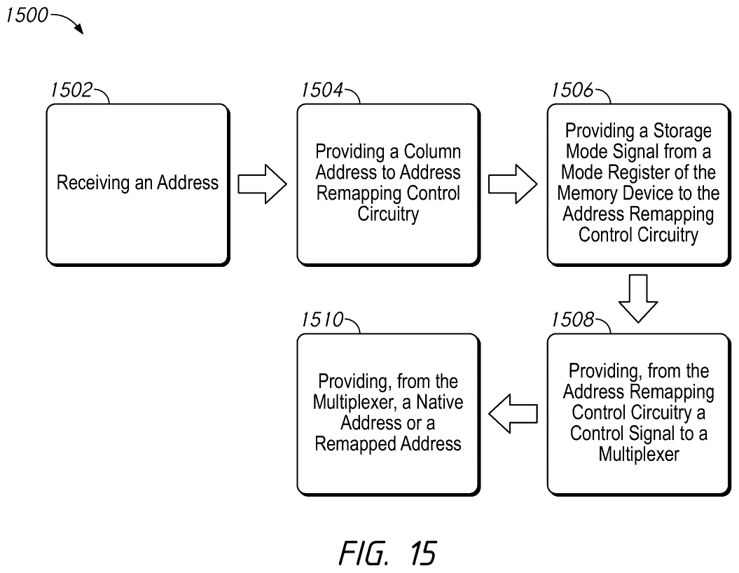

FIG. 15 is a flow chart of a method according to embodiments of the present disclosure. The method shown in flow chart 1500 may be performed in whole or in part by any of the memory devices disclosed herein.

At block 1502, “receiving an address” may be performed. The address may be received at an address decoder of a memory device in some embodiments. At block 1504, “providing a column address to address remapping control circuitry” may be performed. For example, remapping control circuitry 1116 and/or address remapping control circuitry 1280. In some embodiments, the address remapping control circuitry may be included in a column decoder. At block 1506, “providing a storage mode signal from a mode register of the memory device to the address remapping control circuitry” may be performed.

Based on the column address and the storage mode signal, at block 1508, “providing, from the address remapping control circuitry a control signal to a multiplexer” may be performed. For example, one of multiplexers 1108. Responsive to the control signal, at block 1510 “providing, from the multiplexer, a native address or a remapped address” may be performed. In some embodiments, the native address may correspond to an address of a column select when the memory device is in a default storage mode. In some embodiments, the native address may match the logical address in one or more storage modes. For example, in some embodiments, when the memory device is in a default storage mode, the multiplexer outputs the native address. In some embodiments, the remapped address is shifted four places or eight places from the native address.

In some embodiments, the method shown in flow chart 1500 may further include providing the column address to a predecode logic circuit of the memory device, for example predecode logic 1112. The method may further include providing from the predecode logic circuit to the multiplexer, the native address. In these embodiments, the native address may include or may be a predecoded address.

In some embodiments, the predecode logic circuit is shared amongst all of a plurality of column planes of a memory bank of a memory array of the memory device as shown in FIG. 11. In some embodiments, the multiplexer is one of a plurality of multiplexers, and individual ones of the plurality of column planes is associated with different ones of the plurality of multiplexers as shown in FIG. 11.

In some embodiments, the predecode logic circuit decodes six bits of a column address. For example, as shown in FIG. 13.

In some embodiments, the method shown in flow chart 1500 may further include driving the native address or the remapped address to a column decode logic circuit. In some embodiments, the driving is performed by a driver, such as one of drivers 1106. In some embodiments, the driver is one of a plurality of drivers, and individual ones of the plurality of column planes are associated with different ones of the plurality of drivers as shown in FIG. 11.

Memory devices disclosed herein may include data steering circuitry and column decoders that can accommodate multiple storage modes. In some examples, the data steering circuitry and column decoders may include multiplexers and/or tri-state drivers that are controlled by signals that are generated based on the storage mode and column address. In some applications, the embodiments disclosed herein may reduce the number of additional conductive traces and/or decoding circuitry required to accommodate the multiple storage modes.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array including a bank, wherein the bank includes a plurality of column planes;
a first conductive trace coupling a first subset of the plurality of column planes, wherein the first subset includes less than all of the plurality of column planes;
a second conductive trace coupling a second subset of the plurality of column planes, wherein the second subset does not include any of the first subset; and
data steering circuitry configured to selectively steer first data between column planes of the first subset via the first conductive trace and selectively steer second data between column planes of the second subset via the second conductive trace.

2. The apparatus of claim 1, wherein the data steering circuitry includes a plurality of multiplexers configured to selectively steer the first data and the second data based on control signals.

3. The apparatus of claim 2, further comprising:
a mode register configured to provide a mode signal indicating a storage mode of a plurality of storage modes of the memory array; and
an address decoder configured to provide a column address,
wherein the data steering circuitry further includes control circuitry configured to provide the control signals to the plurality of multiplexers based, at least in part, on the mode signal and the column address.

4. The apparatus of claim 3, wherein the control circuitry comprises logic circuits configured to implement a look-up table.

5. The apparatus of claim 2, wherein the plurality of multiplexers are located between a sense amplifier of the memory array and an error correction code circuit.

6. The apparatus of claim 2, wherein the plurality of multiplexers includes:
a first plurality of multiplexers configured to selectively provide the first data or the second data from a native column plane based on the control signals; and
a second plurality of multiplexers configured to selectively provide the first data or the second data from a different column plane than the native column plane based on the control signals.

7. The apparatus of claim 1, wherein the data steering circuitry includes a first plurality of tri-state drivers configured to selectively drive the first data on the first conductive trace and a second plurality of tri-state drivers configured to selectively drive the second data on the second conductive trace responsive to control signals.

8. The apparatus of claim 7, further comprising:
a mode register configured to provide a mode signal indicating a storage mode of a plurality of storage modes of the memory array; and
an address decoder configured to provide a column address,
wherein the data steering circuitry further includes control circuitry configured to provide the control signals to the first plurality of tri-state drivers and the second plurality of tri-state drivers based, at least in part, on the mode signal and the column address.

9. The apparatus of claim 1, wherein an amount of metadata to store in at least one of the plurality of column planes is determined by a storage mode of a plurality of storage modes, wherein:
when the storage mode is a first storage mode of the plurality of storage modes, a first column plane of the first subset and a second column plane of the second subset are configured to store a first amount of metadata,
when the storage mode is a second storage mode of the plurality of storage modes, the first column plane and the second column plane are configured to store a second amount of metadata less than the first amount, and
when the storage mode is a third storage mode of the plurality of storage modes, none of the plurality of column planes store metadata.

10. The apparatus of claim 9, wherein in the second storage mode:
a first plurality of column selects for the first column plane are configured to store the metadata and a second plurality of column selects for the first column plane are configured to store data; and
the first plurality of column selects for the second column plane are configured to store the data and the second plurality of column selects for the second column plane are configured to store the metadata.

11. An apparatus comprising:
a memory array including a bank, wherein the bank includes a plurality of column planes;
a mode register configured to store a value indicating a storage mode of a plurality of storage modes, wherein the memory array is arranged based on the storage mode, wherein the mode register is configured to provide a mode signal based on the value; and
data steering circuitry configured to selectively steer data between column planes of the plurality of column planes based, at least in part, on the mode signal.

12. The apparatus of claim 11, further comprising an address decoder, wherein the address decoder is configured to provide a column address to the data steering circuitry, wherein the data steering circuitry is configured to selectively steer the data further based on the column address.

13. The apparatus of claim 12, wherein the data steering circuitry implements a look-up table based on the column address and the mode signal.

14. The apparatus of claim 11, wherein the data steering circuitry is configured to provide a plurality of control signals to a plurality of multiplexers along a read path of the memory array.

15. The apparatus of claim 11, wherein the data steering circuitry is configured to provide a plurality of control signals to a plurality of tri-state drivers along a write path of the memory array.

16. The apparatus of claim 11, wherein the plurality of column planes are arranged into a plurality of virtual column planes in at least one of the plurality of storage modes.

17. The apparatus of claim 16, wherein a number of the plurality of virtual column planes is less than a number of the plurality of column planes.

18. A method comprising:
receiving an address at a memory device;
providing a column address to data steering circuitry of the memory device;
providing a mode signal from a mode register of the memory device to the data steering circuitry; and
responsive to the column address and the mode signal, selectively steering data between column planes of a bank of a memory array of the memory device.

19. The method of claim 18, further comprising receiving a read command associated with the address, wherein selectively steering comprises steering the data from a metadata column plane to a read path of a data column plane of the bank.

20. The method of 19, wherein steering the data further comprises activating a multiplexer.

21. The method of claim 18, further comprising receiving a write command associated with the address, wherein selectively steering comprises steering the data from a write path of a data column plane to a metadata column plane; and
writing the data to the metadata column plane.

22. The method of claim 21, wherein steering the data further comprises activating a tri-state driver.

23. The method of claim 18, wherein the column address and the mode signal are provided to at least one logic circuit implementing a look-up table.

24. The method of claim 18, further comprising:
receiving a mode register write command and a value to be written to the mode register; and
responsive to the mode register write command, writing the value to the mode register, wherein the mode signal is based on the value.

25. The method of claim 24, wherein:
when the value is a first state, the method further comprises configuring a first column plane and a second column plane of the memory array to store metadata and configuring a plurality of column planes to store the data; and
when the value is a second state, the method further comprises configuring the first column plane, the second column plane, and the plurality of column planes to store the data.
